(19) United States
(12) Patent Application Publication
(10) Pub. No.: US 2006/0160272 A1
(43) Pub. Date: Jul. 20, 2006

(54) Synthesis method for a compound used to form a self-assembled monolayer, compound for forming a self-assembled monolayer, and layer structure for a semiconductor component

(76) Inventors: Franz Effenberger, Stuttgart (DE); Markus Schuetz, Stuttgart (DE); Steffen Maisch, Gerlingen (DE); Steffen Seifritz, Gladbeck (DE); Guenter Schmid, Hemhofen (DE); Marcus Halik, Erlangen (DE); Hagen Klauk, Stuttgart (DE); Ute Zschieschang, Stuttgart (DE); Stefan Holberg, Aarhus (DK)

Correspondence Address: SLATER & MATSIL LLP, 17950 PRESTON ROAD, SUITE 1000, DALLAS, TX, 75252, US

(21) Appl. No.: 11/313,235

(22) Filed: Dec. 20, 2005

Related U.S. Application Data
(63) Continuation of application No. PCT/DE04/01319, filed on Jun. 18, 2004.

(30) Foreign Application Priority Data
Jun. 20, 2003 (DE) 103 28 810.4

(51) Int. Cl. H01L 21/50

(52) U.S. Cl. 438/110

(57) ABSTRACT

A synthesis method of a compound used to form a self-assembled monolayer used in a semiconductor component is provided. A method includes a first step of replacing a terminal halogen of an ω-haloalk-1-ene with a compound having at least one aromatic group, and a second step of hydrosilylating the reaction product of the first step. Reaction products of the first step include octadec-17-enyloxybenzene, 4-octadec-17″-enyloxy-1,1′-biphenyl, 2-heptadec-16′-enylthiophene, and 2-octadec-17′-enylthiophene. Monolayers provided include 18-phenoxyoctadecyl)trichlorosilane, [18-(1′,1″-biphenyl-4′-yloxy)octadecyl]trichlorosilane, (17-thien-2′-ylheptadecyl)trichlorosilane, (18-thien-2′-yloctadecyl)trichlorosilane, and 4-(18′-trichlorosilyloctadecyloxy)benzonitrile. An organic field effect transistor having monolayers according to embodiments of the invention is provided.

This application is a continuation of co-pending International Application No. PCT/DE2004/001319, filed Jun. 18, 2004, which designated the United States and was not published in English, and which is based on German Application No. 103 28 810.4 filed Jun. 20, 2003, both of which applications are incorporated herein by reference.

### TECHNICAL FIELD

The invention relates to semiconductor manufacturing and more particularly to organic field effect transistors (OFET) and semiconductor components having organic compounds, organic monolayers, and organic layer structures.

### BACKGROUND

Increasingly, semiconductor components are being produced using organic materials. For example, field effect transistors based on organic semiconductors (OFET) are of interest for a large number of electronic applications. In particular, low manufacturing costs, flexible or unbreakable substrates or the production of transistors and integrated circuits over large active areas are possible therewith. For example, organic field effect transistors are suitable as pixel control elements in active matrix screens or for the production of extremely economical integrated circuits, as used, for example, for the active marking and identification of products and goods.

Since complex circuits may be built up using organic field effect transistors, there are numerous potential applications. Thus, for example, the introduction of RF-ID (RF-ID: radio frequency identification) systems based on this technology is considered a potential replacement for the barcode, which is susceptible to faults and may be used only in direct optical contact with the scanner. Passive RF-ID systems obtain their energy from the incident alternating field.

The possible distance between reader and transponder depends on the radiant power and the energy requirement of the transponder. Silicon-based transponders therefore operate at supply voltages of about 3 V. Products which contain a silicon-based chip are too expensive for many applications. For example, a silicon-based identification tag is not suitable for the marking of foods (price, expiry date, etc.).

Organic field effect transistors usually consist of at least four different layers applied one on top of the other: a gate electrode, a dielectric, a source-drain contact layer and an organic semiconductor. The sequence of the layers may vary. To ensure the functionality, the individual layers must be structured, which is relatively complicated.

Polymers or organic semiconductors offer the potential of being able to use cheap printing techniques for less structuring and application. The gate potential for controlling the organic field effect transistors may be chosen to be all the lower but thinner in the form in which the gate dielectric (i.e., a dielectric layer) may be produced.

In polymer electronics, the thickness of the gate dielectric is generally optimized so that the solution of a polymer is spun out or printed on increasingly thinly (top-down). However, this procedure encounters its limits when it is intended to achieve layer thicknesses of less than 50 nm.

It is known that layers for organic field effect transistors may be built up by means of self-assembled layers comprising molecular monolayers (SAM: self-assembled monolayers).

In the articles by J. Collet, D. Vuillaume; “Nano-field effect transistor with an organic self-assembled monolayer as gate insulator”, Applied Physics Letters 73 (1998) 2681; J. Collet, S. Lenfant, D. Vuillaume, O. Bouloussa, F. Rondelez, J. M. Gay, K. Kham, C. Chevrot; “High anisotropic conductivity in organic insulator/semiconductor monolayer heterostructure”, Applied Physic Letters 76 (2000) 1339, and J. Collet, O. Tharaud, A. Chapoton, D. Vuillaume; “Low-voltage, 30 nm channel length, organic transistors with a self-assembled monolayer as gate insulating films”, Applied Physics Letters 76 (2000) 1941, which describe such layers.

These layers are also discussed in the articles by Pradyt Ghosh, Richard M. Crooks; “Covalent Grafting of a Pattered”, Hyperbranched Polymer onto Plastic Substrate Using Microcontact Printing”, J. Am. Chem. Soc. 121 (1999) 8395-8306, and William M. Lackowski, Pradyut Ghosh, Richard M. Crooks; “Micron-Scale Patterning of Hyperbranched Polymer Films by Micro-Contact Printing;”, J. Am. Chem. Soc. 121 (1999) 1419-1420, and U.S. Pat. No. 4,539,061.

The articles by Collet et al. describe materials which make it possible to build up transistors having SAM layers. Vinyl-terminated silanes have anchor groups on hydroxyl-containing substrate surfaces to form an SAM. This is subsequently chemically aftertreated in order to bind further molecules chemically to the SAM (cf. U.S. Pat. No. 4,539,061), or surfaces which permit further processing are produced (cf. article by Collet, Tharaud et al.).

It is disadvantageous that these layers do not form a dense dielectric layer without aftertreatment. The chemical aftertreatments used converts only 70 to 90% of the terminal group in a reaction time of 48 to 120 hours. This chemical aftertreatment takes too long for the production of large quantities.

In principle, it is also possible to bind polymers via a plurality of coordination sites to a surface (Self-Assembled Polymers). This is disclosed in U.S. Pat. No. 5,728,431, U.S. Pat. No. 5,783,648 (1998) and U.S. Pat. No. 5,686,549.

### SUMMARY OF THE INVENTION

Embodiments of the present invention provide an efficient synthesis method for a compound capable of a π-π interaction with other compounds of the same type and/or compounds of a different type. Furthermore, embodiments provide suitable compounds and a layer structure which may be used efficiently for the production of semiconductor components.

An embodiment of the invention provides a method for a compound used to form a self-assembled monolayer, preferably a monolayer for a semiconductor component.

In a first synthesis step, in the case of an ω-haloalk-1-ene (I), 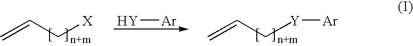
a terminal nucleophilic substitution of the halogen by a group capable of a π-π interaction, in particular a group having at least one aromatic group (Ar), is carried out. The product of the first synthesis step is then hydrosilylated in a second synthesis step.

Owing to the high yield and the possibility of easy purification, economical preparation of suitable compounds is permitted by this two-stage synthesis method.

Other embodiments of the invention provide compounds for forming self-assembled monolayers, preferably monolayers for semiconductor components. In an embodiment, the compounds are used for a dielectric layer having a stabilizing head group. The head groups interact with one another in order to provide a stable surface of a molecular monolayer which may be easily further structured.

Such a monolayer can then be used in a semiconductor component layer structure according to the invention, in particular in an organic field effect transistor.

Advantageous developments are described in the appended claims.

### BRIEF DESCRIPTION OF THE DRAWINGS

The invention is explained in more detail below in a plurality of embodiments with reference to the figures of the drawing.

FIG. 1 shows a general reaction scheme of the first two steps of the synthesis method;

FIG. 2 shows aromatic groups capable of a π-π interaction;

FIG. 3 shows a general reaction scheme for a synthesis of an ω-haloalk-1-ene;

FIG. 4 shows the reaction scheme for the synthesis of 18-bromooctadec-1-ene;

FIG. 5 shows the structural formula for 8-bromooct-1-ene;

FIG. 6 shows the structural formula for 18-bromooctadec-1-ene;

FIG. 7 shows the reaction scheme of the synthesis of (18-phenoxyoctadecyl)trichlorosilane;

FIG. 8 shows the structural formula for octadec-17-enyloxybenzene;

FIG. 9 shows the structural formula for (18-phenoxyoctadecyl)trichlorosilane;

FIG. 10 shows the reaction scheme for the synthesis of [18-(1′,1″-biphenyl-4′-yloxy)octadecyl)]trichlorosilane;

FIG. 11 shows the structural formula for 4-octadec-17″-enyloxy-1,1′-biphenyl;

FIG. 12 shows the structural formula for [18-(1′,1″-biphenyl-4′-yloxy)octadecyl)]trichlorosilane;

FIG. 13 shows the reaction scheme for the synthesis of (17-thien-2′-ylheptadecyl)trichlorosilane (a) and (18-thien-2′-yloctadecyl)trichlorosilane (b);

FIG. 14 shows the structural formula for 2-heptadec-16′-enylthiophene;

FIG. 15 shows the structural formula for (17-thien-2′-ylheptadecyl)trichlorosilane;

FIG. 16 shows the structural formula for 2-octadec-17′-enylthiophene;

FIG. 17 shows the structural formula for (18-thien-2′-yloctadecyl)trichlorosilane;

FIG. 18 shows the reaction scheme for the synthesis of 4-(18′-trichlorosilyloctadecyloxy)benzonitrile;

FIG. 19 shows the structural formula for 4-octadec-17′-enyloxybenzonitrile;

FIG. 20 shows the structural formula for 4-(18′-trichlorosilyloctadecyloxy)-benzonitrile;

FIG. 21 shows a structural formula of an embodiment of the compound according to the invention;

FIG. 22 shows a monolayer for the formation of a layer structure with an embodiment of the compound according to the invention on a substrate; and

FIG. 23 shows a schematic structure of an organic field effect transistor.

The following list of reference symbols may be used in conjunction with the figures:
1 Anchor group
2 Dielectric group
3 Group having a π-π interaction (head group)
5 Compound for the formation of a self-assembled layer
10 Substrate
11 Monolayer of molecules
20 Base substrate for OFET
21 Gate electrode
22 Gate dielectric layer
23a Source layer
23b Drain layer
24 Active semiconductor layer
25 Passivation layer
100 Semiconductor component (organic field effect transistor)

### DETAILED DESCRIPTION OF ILLUSTRATIVE EMBODIMENTS

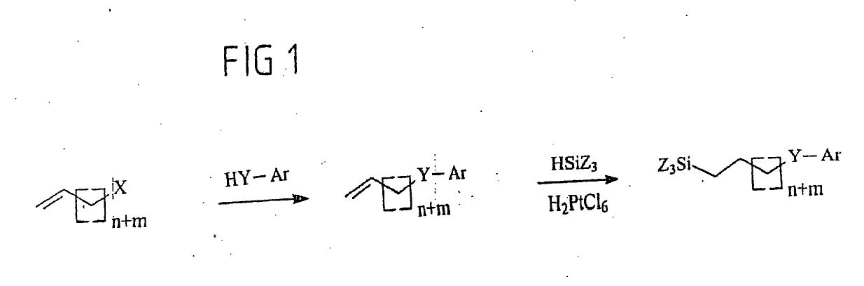

In FIG. 1, an embodiment of the synthesis method according to the invention is described.

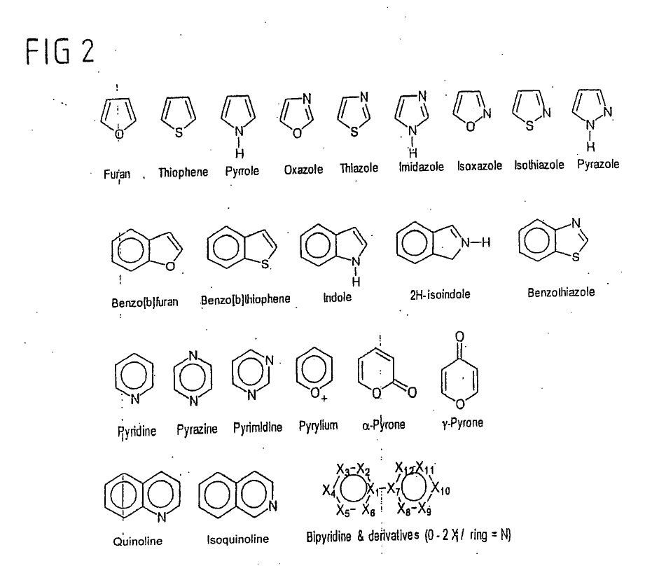

The starting material is an ω-haloalk-1-ene (I). A substituted halogen X is present at that end of the chain, which is opposite the double bond. This ω-haloalk-1-ene (I) is prepared from two shorter chains (chain lengths n, m) in a manner still to be described (cf. FIG. 2). In the example of FIG. 1, n=6, m=10 and X═Cl, Br or I.

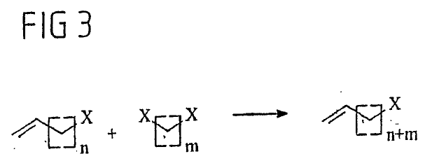

In the first synthesis step, the halogen X is substituted by a group containing an aromatic group Ar having the general formula
HY—Ar
with Y: O, S, Se or —NH. At least one of the groups according to FIG. 3 may be used as aromatic groups. A naphthalene, anthracene, naphthacene, pentacene, biphenyl, terphenyl, quaterphenyl and/or quinquephenyl may also be used. An aromatic group Ar or a multi-ring system comprising identical or different groups may be used.

After the first synthesis step, a product present is one which has an aromatic head group which is capable of a π-π interaction with other molecules. This product is subjected to a hydrosilylation in the second synthesis step. The molecule is silylated at that end of the chain which is opposite the head group. In the example of FIG. 1, HSiZ₃ with Z: Cl or alkoxy group is used. The reaction advantageously takes place under acid catalysis, in this case with hexachloro-platinic(IV) acid (H₂PtCl₆).

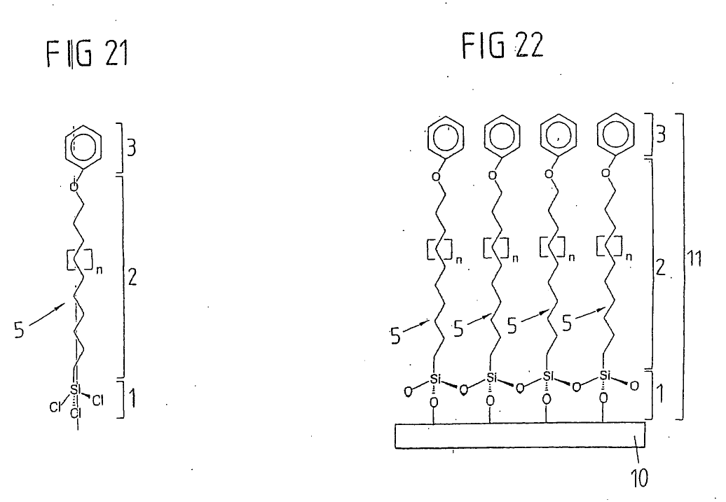

In addition to the aromatic head group, the product of the synthesis step has a silane anchor group which can form a bond with a substrate or a layer on a substrate. This is explained in more detail with reference to FIGS. 21 and 22.

FIG. 2 shows aromatic groups Ar capable of a π-π interaction. It is also possible to use another aromatic compound, in particular at least one naphthalene, anthracene, naphthacene, pentacene, biphenyl, terphenyl, quaterphenyl and/or a quinquephenyl.

Chains having in each case different aromatic ring systems in the chain are also possible. The properties may be readily established by means of the length of the condensed chains. Smaller aromatics which are generally not highly condensed and which do not disturb the substantially monocrystalline or epitactic two-dimensional structure of the monolayer 11 (cf. FIG. 22) are particularly suitable.

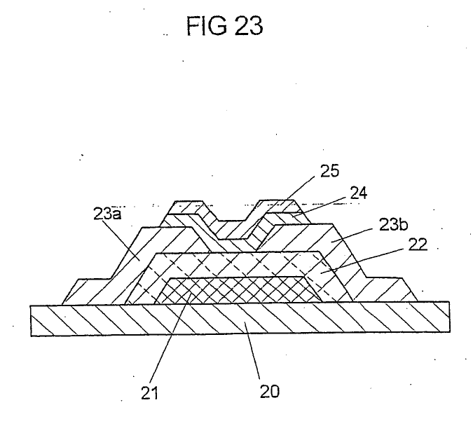

By means of these interactions, it is possible to form layers which are suitable for dielectrics in organic field effect transistors (cf. FIG. 23).

The π-π interaction occurs spontaneously in the monolayers 11 and need not be initiated. In principle, such groups for the formation of a π-π interaction can also be introduced within the SAM, but can then no longer be referred to as head groups.

FIG. 3 shows, as one embodiment, a general reaction for the preparation of an ω-haloalk-1-ene, i.e. a preliminary reaction to the two above-mentioned synthesis steps. The ω-haloalk-1-ene is the starting material for the first synthesis step. The halogen X is preferably Cl, Br or I; in this case Br. Preferably, n may be from 2 to 12; in the example, n is 6. The chain length of the second reactant m may be between 5 and 15; in this case, m is 10.

Stages of embodiments of the synthesis according to the invention are described below.

### EXAMPLE 1.1

### Preparation of 18-bromooctadec-1-ene

Compounds having alkyl chains and different substituents in the α- and ω-position are commercially available only up to a chain length of 12 carbon atoms. For longer-chain compounds, ω-bromoalkenes are frequently used starting materials since a large number of simple reactions makes it possible selectively to convert one of the in the case of the functional groups. This is a preparatory step for the synthesis according to the invention, a halogenated 1-alkene then reacts further.

Heid prepares bromoheptadec-1-ene from the Grignard compound of 5-bromopent-1-ene and an excess of 1,12-dibromododecane using a lithium-copper-catalyzed coupling reaction in 66% yield and made it possible to dispense with the complicated medium-pressure chromatographic purification required in the earlier methods (S. R. Wassermann, Y.-T. Tao, G. M. Whitesides, Langmuir 1989, 5, 1074). Excess starting material and the byproduct docosa-1,21-diene formed from a double reaction are separated off by double chromatography. 18-Bromooctadec-1-ene was synthesized analogously from 6-bromohex-1-ene, with only 12% yield owing to a secondary reaction (F. Effenberger, S. Heid, Synthesis 1995, 1126).

In the present example, a chromatographic purification, which is very complicated in the case of the preparation of amounts greater than 10 g, could be completely dispensed with by a skillful choice of the starting materials. The Grignard compound of 8-bromooct-1-ene was reacted with an excess of 1,10-dibromodecane under the conditions worked out by S. Heid (S. Heid, Thesis, Stuttgart, 1994, page 197 et seq.).

The byproducts differ in the boiling point from the product so substantially that simple distillation over a 20 cm Vigreux column is sufficient for isolating a reagent grade product in 60% yield.

8-Bromooct-1-ene was prepared under the same conditions from allyl bromide and 1,5-dibromopentane and, after distillation over a 60 cm split tube column, was isolated as a reagent grade product in 60% yield.

The synthesis of 8-bromooct-1-ene in a yield of 33%, based on allylmagnesium bromide, was published by Johnson et al. (D. K. Johnson, J. Donohoe, J. Kang, Synth. Commun. 1994, 24, 1557).

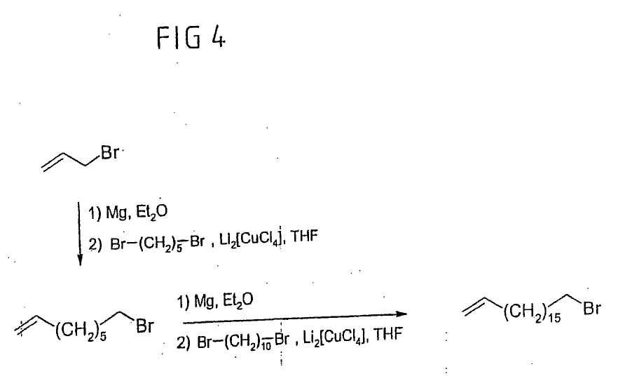

The synthesis steps from allyl bromide to 18-bromooctadec-1-ene are shown in FIG. 4 and are described below.

### Preparation of 8-bromooct-1-ene

Batch:

| | | | | |
|---|---|---|---|---|
| Allyl bromide: | 87 | ml | 1.00 | mol |
| Magnesium: | 50.1 | g | 2.06 | mol |
| 1,5-Dibromopentane: | 296 | ml | 2.17 | mol |
| Li₂CuCl₄ solution: | 0.5 | ml | 0.05 | mmol |
| Diethyl ether: | 660 | ml | | |
| THF: | 200 | ml | | |

Grignard reaction: Magnesium in ether is initially introduced into a heated flask having an Ar atmosphere. Allyl bromide (dissolved in ether) is added via a dropping funnel so that the solvent boils gently. The solution is then heated to the boil for a further 90 min.

Preparation of the copper lithium catalyst: 1 mmol (134.5 mg) of CuCl₂ and 2 mmol (84.8 mg) of LiCl—both dried beforehand over P₄O₁₀ under a vacuum from an oil pump—are dissolved in 10 ml of absolute THF (tetrahydrofuran). The deep red solution is stirred until complete dissolution of the solid and is stored in a refrigerator.

Cross-coupling: 1,5-Dibromopentane in THF is initially introduced into a second flask (heated and under an inert gas atmosphere) and is cooled to 0° C. Before the transfer of the Grignard compound by means of a Teflon cannula, the catalyst is added. Immediately after addition of the Grignard compound, a color change from reddish through green to colorless takes place. After addition is complete, the reaction is brought to room temperature and stirred overnight.

Working-up: After addition of water, neutralization is effected with 300 ml of saturated ammonium chloride solution and the phases are separated in a separating funnel. After the phase separation, the organic phase is evaporated down in vacuo at about 40° C. down to 100 mbar, taken up in 300 ml of dichloromethane and washed twice with 200 ml of water. The organic phase thus obtained is dried over magnesium sulfate and the solvent is removed in vacuo.

Fractional distillation is then effected over a 60 cm split tube column (reflux ratio 20:1). In addition to pure product, pure 1,5-dibromopentane is thus also recovered.

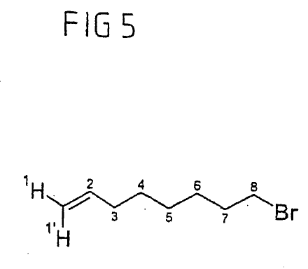

Yield: 115 g (602 mmol) of 60% 8-bromooct-1-ene (cf. FIG. 5); colorless liquid

Boiling point: 1,10-Undecadiene: about 80° C.
8-Bromooct-1-ene: 94-97° C.
1,5-Dibromopentane: 110-112° C.
In each case at 15 mmHg

Analysis: C₈H₁₅Br (M: 191.11 g/mol) Calc.: C: 50.28 H: 7.91 Br: 41.81 Found: C: 50.03 H: 7.81 Br: 41.97

¹H-NMR: (500 MHz, CDCl₃) 1.30 to 1.47 (m; 6H; H4 to H6); 1.86 (m, 2H; H7); 2.05 (m; 2H; H3); 3.41 (t; ³J_{8,7}=6.9 Hz; 2H; H8); 4.94 (m_{c}; 1H; H1); 5.00 (m_{c}; 1H; H1′); 5.80 (ddt; 1H; H2; ³j_{2,1}=17.0 Hz; ³j_{2,1}=10.3 Hz; ³j_{2,3}=6.9 Hz)

¹³C-NMR: (126 MHz, CDCl₃) 28.4; 28.6; 29.1 (C4 to C6); 33.2 (C7); 34.0 (C3); 34.4 (C8); 114.8 (C1); 139.3 (C2)

### Preparation of 18-Bromooctadec-1-ene

| | | | | |
|---|---|---|---|---|
| Batch: | 8-Bromooct-1-ene | 9.60 | g | 50.2 mmol |
| | Magnesium | 2.00 | g | 82.3 mmol |
| | Et₂O: | 90 | ml | |
| | 1,10-Dibromodecane: | 25.0 | g | 111 mmol |
| | Li₂CuCl₄ solution: | 100 | μl | |
| | THF: | 50 | ml | |

Grignard reaction: Magnesium in ether is initially introduced into a heated flask having an Ar atmosphere. 8-Bromooct-1-ene (dissolved in ether) is added via a dropping funnel so that the solvent boils gently. The solution is then heated to the boil for a further 2 h.

Preparation of the copper lithium catalyst: 1 mmol (134.5 mg) of CuCl₂ and 2 mmol (84.8 mg) of LiCl—both dried beforehand over P₄O₁₀ under a vacuum from an oil pump—are dissolved in 10 ml of absolute THF. The deep red solution is stirred until complete dissolution of the solid and is stored in a refrigerator.

Cross-coupling: 1,10-Dibromodecane in THF is initially introduced into a second flask (heated and under an inert gas atmosphere) and is cooled to 0° C. Before the transfer of the Grignard compound by means of a Teflon cannula, the catalyst is added. Immediately after addition of the Grignard compound, a color change from reddish through green to colorless takes place. After addition is complete, the reaction is brought to room temperature and stirred overnight.

The reaction of 8-bromooct-1-ene and 1,10-dibromodecane to give 18-bromooctadec-1-ene (FIG. 4) is an example of the general reaction for the preparation of the ω-haloalk-1-ene according to FIG. 3.

Working-up: Water is added in an amount such that all of the MgBr₂ dissolves. The phases are then separated in a separating funnel.

The organic phase is washed twice with water and then dried over MgSO₄ and the solvent is removed in vacuo. The product is subjected to fractional distillation in vacuo at 0.04 mmHg over a Vigreux column at 132-137° C.

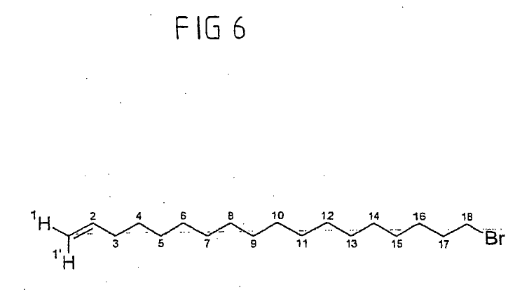

Yield: 9.98 g (30.1 mmol) of 60% 18-bromooctadec-1-ene (cf. FIG. 6); colorless liquid

Boiling point: 132-137° C. at 0.04 mmHg

Analysis: C₈H₁₅Br (M: 331.38 g/mol) Calc.: C: 65.24 H: 10.65 Br: 24.11 Found: C: 65.38 H: 10.63 Br: 24.04

¹H-NMR: (500 MHz, CDCl₃) 1.22 to 1.43 (m; 22H; H4 to H14); 1.85 (m; 2H; H17); 2.04 (m; 2H; H3); 3.40 (t; 2H; H18; ³J_{18,17}=6.8 Hz); 4.93 (m_{c}; 1H; H1); 4.99 (m_{c}; 1H; H1′); 5.81 (ddt; 1H; H2; ³J_{2,1′}=17.1 Hz; ³J_{2,1}=10.3 Hz; ³j_{2,3}=6.8 Hz)

¹³C-NMR: (126 MHz, CDCl₃) 28.2; 28.8; 29.0; 29.2; 29.5; 29.5; 29.6; 29.6; 29.7 (C4 to C16); 32.9 (C17); 33.8 (C3); 34.0 (C18); 114.1 (C1); 139.2 (C2)

### EXAMPLE 1.2

### Preparation of (18-Phenoxyoctadecyl)trichlorosilane

18-Bromooctadec-1-ene obtained in example 1.1 is now reacted further.

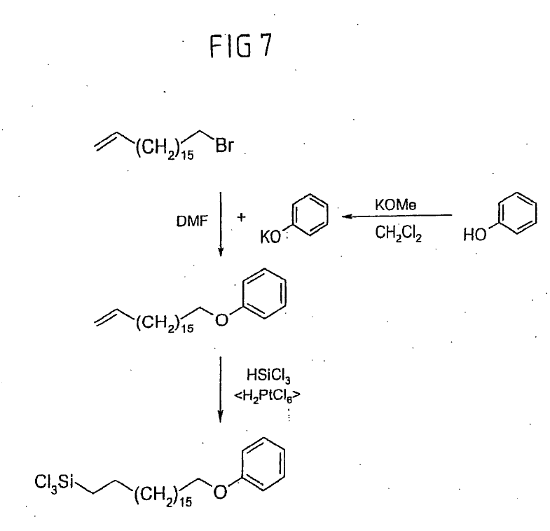

The following synthesis steps are embodiments for the synthesis method according to the invention, which consists of two synthesis steps. An embodiment comprising both synthesis steps is shown in FIG. 7, both of them being described below.

In the first synthesis step for the synthesis of octadec-17-enyloxybenzene, potassium phenolate, prepared from phenol and potassium methanolate, is reacted with 18-bromooctadecene (cf. example 1.1) in DMF (N,N-dimethylformamide). After working-up and column filtration, octadec-17-enyloxybenzene was present in reagent grade purity in a yield of 88% for further reaction.

The trichlorosilane is then synthesized from the alkenyl phenyl ether in the second synthesis step in a platinum-catalyzed hydrosilylation.

As shown by ¹H— and ¹³C-NMR and mass spectroscopy, this could be obtained in pure form after final purification by bulb-tube distillation in 88% yield, based on octadec-17-enyloxybenzene.

The two synthesis steps are described in detail below.

### 1st synthesis step: Preparation of octadec-17-enyloxybenzene

| | | | | |
|---|---|---|---|---|
| Batch: | Phenol: | 4.26 | g | 45.3 mmol |
| | KOMe: | 3.08 | g | 43.9 mmol |
| | CH₂Cl₂: | 100 | ml | |
| | 18-Bromooctadecene: | 10 | g | 30.2 mmol |
| | DMF: | 100 | ml | |

Preparation of potassium phenolate: Phenol in CH₂Cl₂ is initially introduced into a flask, and KOMe is added. The reaction mixture is stirred for 15 min at room temperature, after which the solvent is completely removed in vacuo.

Ether coupling: DMF and the corresponding alkyl bromide are added to potassium phenolate and heated to 150° C. After 2 h, the reaction is brought to room temperature, water is added and neutralization is effected with dilute HCl.

Working-up: The aqueous DMF phase is extracted several times with ether in a separating funnel. The organic phase is washed DMF-free with water and dried over MgSO₄. After removal of the solvent and purification of a silica gel with PE/CH₂Cl₂ (1:1) as mobile phase, a colorless solid is obtained.

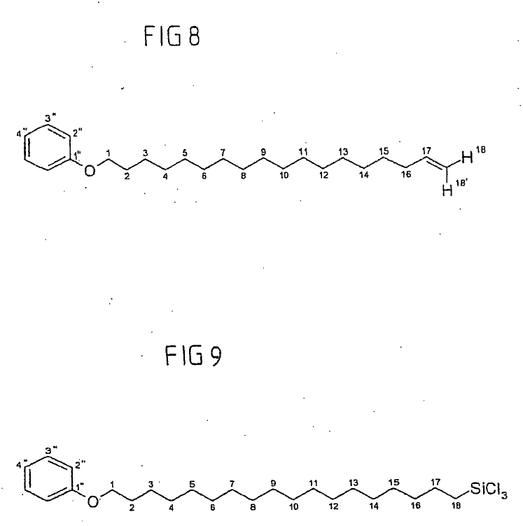

Yield: 9.18 g (26.6 mmol) of 88% octadec-17-enyloxybenzene (cf. FIG. 8); colorless solid

Melting point: 44-45° C.

TLC (PE/CH₂Cl₂=1:1): R_{f}=0.65

Analysis: C₂₄H₄₀O (M: 344.58 g/mol) Calc.: C: 83.56 H: 11.70 O: 4.64 Found: C: 83.66 H: 11.79 O: —

¹H-NMR: (500 MHz, CDCl₃) 1.22 to 1.39 (m; 24H; H4 to H15); 1.44 (m; 2H; H3); 1.77 (m; 2H; H2); 2.04 (m; 2H; H16); 3.95 (t; 2H; H1; ³J_{1,2}=6.6 Hz); 4.93 (m,; 1H; H18); 4.99 (m_{c}; 1H; H18′); 5.81 (ddt, 1H; H17; ³j_{17,18′}=17.0 Hz; ³J_{17,18}=10.2 Hz; ³J_{17,16}=6.6 Hz); 6.90 (m, 3H; H4″+H2″); 7.27 (m; 2H; H3″)

¹³C-NMR: (126 MHz, CDCl₃) 26.0; 29.0; 29.2; 29.3; 29.4; 29.5; 29.5; 29.5; 29.5; 29.7 (C2 to C15); 33.8 (C16); 67.9 (C1); 114.1 (C18); 114.5 (C2″); 120.4 (C4″); 129.4 (C3″); 139.3 (C17); 159.1 (C1″)

### 2nd synthesis step: Preparation of (18-Phenoxyoctadecyl)trichlorosilane

| | | | | |
|---|---|---|---|---|
| Batch: | Octadec-17-enyloxybenzene: | 3 | g | 8.71 mmol |
| | Trichlorosilane: | 8.8 | ml | 87.1 mmol |
| | Hexachloroplatinic acid solution: | 10 | drops | |

Octadec-17-enyloxybenzene is initially introduced into a heated two-necked flask having a reflux condenser/gas discharge tube with valve/argon balloon and rubber septum. Trichlorosilane and the catalyst solution are added by means of a syringe and stirring is effected overnight at room temperature.

After removal of the excess trichlorosilane under a vacuum from a water jet pump, the residue is distilled in the bulb tube under a vacuum from an oil pump.

Preparation of the catalyst solution: 164 mg of H₂PtCl₆ aq. are dissolved in 10 ml of absolute isopropanol. The solution is stirred until complete dissolution of the solid and is stored in a refrigerator.

Yield: 3.66 g (7.63 mmol) of 88% (18-phenoxyoctadecyl)trichlorosilane (cf. FIG. 9); colorless solid

Melting point: 34° C.

Boiling point: 185-195° C. at 1×10⁻³ mmHg

MS (EI 70 eV) C₂₄H₄₁Cl₃OSi Calc: 478.1992 Found: 478.1991

¹H-NMR: (250 MHz, CDCl₃) 1.26 to 1.42 (m; 30H; H3 to H17), 1.57 (m; 2H; H18); 1.78 (m; 2H; H2); 3.95 (t; 2H; H1; ³J_{1,2}=6.6 Hz); 6.92 (m; 3H; H4″+H2″); 7.27 (m; 2H; H3″)

¹³C-NMR: (63 MHz, CDCl3) 22.2 (C18); 24.3 (C17); 29.1; 29.0; 29.3; 29.4; 29.4; 29.6; 29.7 (C2 to C15); 31.8 (C16); 67.8 (C1); 114.4 (C2″); 120.4 (C4″); 129.4 (C3″); 159.1 (C1″)

The product is a compound, which may be used in the production of monolayers in the production of organic semiconductor elements. This is described in FIGS. 22 and 23.

### EXAMPLE 2

### Preparation of [18-(1′1″-Biphenyl-4′-yloxy)octadecyl]trichlorosilane

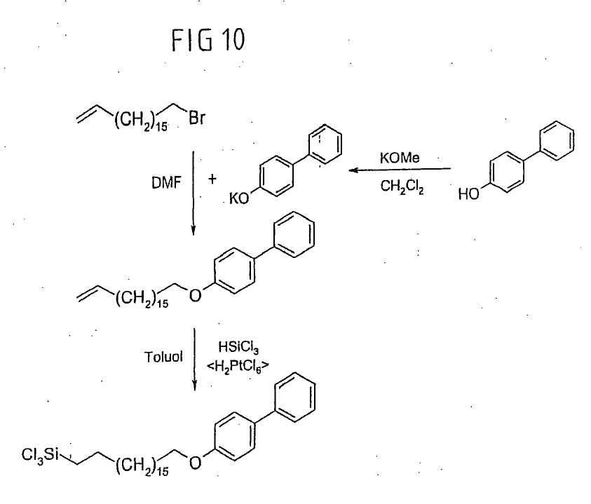

This embodiment of the synthesis method according to the invention is effected analogously to the synthesis of (18-phenoxyoctadecyl)trichlorosilane (example 1.2) starting from 18-bromooctadec-1-ene in two synthesis steps (cf. FIG. 10).

This is reacted in the first synthesis step in DMF with potassium biphenyl-4-olate, prepared from biphenyl-4-ol and potassium methylate.

The intermediate 4-octadec-17″-enyloxy-1,1′-biphenyl could be obtained in reagent grade purity in 79% yield after recrystallization from dichloromethane.

In the second synthesis step, the alkenyl phenyl ether formed as an intermediate is converted in a platinum-catalyzed hydrosilylation into [18-(1′1″-biphenyl-4′-yloxy)-octadecyl]trichlorosilane.

Since the 4-octadec-17″-enyloxy-1,1′-biphenyl dissolves poorly in trichlorosilane, toluene was added as a cosolvent. After final distillation, pure trichlorosilane was obtained in 88% yield. This was demonstrated by mass spectroscopy and ¹H— and ¹³C-NMR spectroscopy. Synthesis steps are described in detail below.

### 1st synthesis step: Synthesis of 4-octadec-17″-enyloxy-1,1′-biphenyl

| | | | | |
|---|---|---|---|---|
| Batch: | 4-Hydroxybiphenyl: | 10.3 | g | 60.4 mmol |
| | KOMe: | 4.43 | g | 63.2 mmol |
| | CH₂Cl₂: | 180 | ml | |
| | 18-Bromooctadecene | 15.8 | g | 47.5 mmol |
| | DMF: | 80 | ml | |

Preparation of potassium phenolate: 4-Hydroxybiphenyl in CH₂Cl₂ are initially introduced into a flask, and KOMe is added. The reaction mixture is stirred for 15 min at room temperature, after which the solvent is completely removed in vacuo.

Ether coupling: DMF and 18-bromooctadec-1-ene are added to potassium phenolate and heated to at 110° C. After 2 h, the reaction is brought to room temperature, water is added and neutralization is effected with dilute HCl.

Working-up: The aqueous DMF phase is extracted three times with hot dichloromethane in a separating funnel. The organic phase is washed DMF-free twice with water and dried over MgSO₄. After removal of the solvent, the solid obtained is recrystallized three times from dichloromethane.

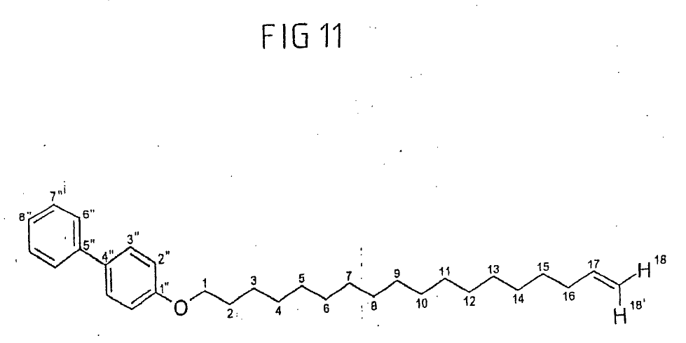

Yield: 15.8 g (37.5 mmol) of 79% 4-octadec-17″-enyloxy-1,1′-biphenyl (cf. FIG. 11); colorless solid

Melting point: 86° C.

Analysis: C₂₄H₄₀O (M: 420.68 g/mol) Calc: C: 85.65 H: 10.54 O: 3.80 Found: C: 85.78 H: 10.66 O: —

¹H-NMR: (500 MHz, CDCl3) 1.26 to 1.39 (m; 24H; H4 to H15); 1.47 (m; 2H; H3); 1.80 (m; 2H; H2); 2.04 (m; 2H; H16); 3.99 (t; 2H; H1; ³J_{1,2}=6.6 Hz); 4.92 (m_{c}; 1H; H18); 4.99 (m_{c}; 1H; H18′); 5.81 (ddt; 1H; H17; ³J_{17,18′}=17.0 Hz; ³J_{17,18}=10.3 Hz; J_{17,16}=6.7 Hz); 6.96 (m; 2H; H2″); 7.29 (m; 1H; H8″); 7.41 (m; 2H; H7″); 7.51 (m; 2H; H3″); 7.54 (m; 2H; H6″)

¹³C-NMR: (126 MHz, CDCl3) 26.1; 29.0; 29.2; 29.3; 29.4; 29.5; 29.6; 29.6; 29.6; 29.7 (C2 to C15); 33.8 (C16); 68.1 (C1); 114.1 (C18); 114.8 (C2″); 126.6 (C8″); 126.7 (C6″); 128.1 (C3″); 128.7 (C7″); 133.5 (C4″); 139.3 (C17); 140.9 (CS″); 158.7 (C1″)

### 2nd synthesis step: Preparation of [18-(1′,1″-biphenyl-4′-yloxy)octadecyl]-trichlorosilane

| | | | | |
|---|---|---|---|---|
| Batch: | 4-Octadec-17″-enyloxy-1,1′-biphenyl: | 6 | g | 14.26 mmol |
| | Trichlorosilane: | 8.3 | ml | 82.23 mmol |
| | Hexachloroplatinic acid solution: | 100 | μl | |
| | Toluene: | 30 | μl | |

In a heated two-necked flask having a reflux condenser/gas discharge tube with valve/argon balloon and rubber septum, the olefin is initially introduced. Trichlorosilane and the catalyst solution are added by means of a syringe. Since the starting material 4-octadec-17″-enyloxy-1,1′-biphenyl dissolves poorly in trichlorosilane, an additional 30 ml of absolute toluene are added as a cosolvent. Stirring is effected overnight at room temperature.

After removal of the excess trichlorosilane and of the toluene in a vacuum from a water jet pump, the residue is distilled over a Vigreux column under a vacuum from an oil pump.

Preparation of the catalyst solution: 164 mg of H₂PtCl₆ aq. are dissolved in 10 ml of absolute isopropanol. The solution is stirred until complete dissolution of the solid and is stored in a refrigerator.

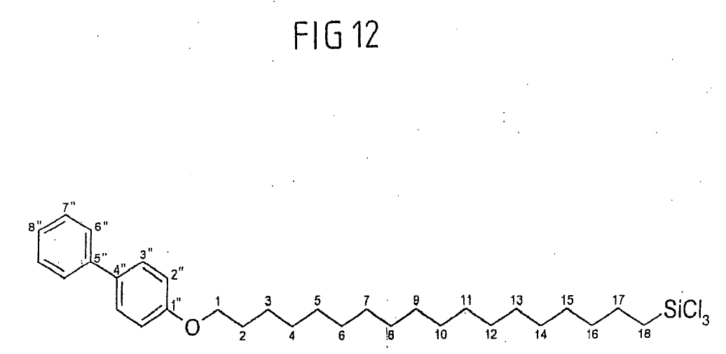

Yield: 7.01 g (12.6 mmol) of 88% [18-(1′,1″-biphenyl-4′-yloxy)octadecyl]-trichlorosilane (cf. FIG. 12); colorless solid

Boiling point: 249-263° C. at 3×10⁻⁵ mbar

Melting point: 115° C.

MS (EI positive ion) C₃₀H₄₅Cl₃Osi Calc.: 554.2305 Found: 554.2296

¹H-NMR: (500 MHz, CDCl3) 1.26 to 1.43 (m; 28H; H4 to H17), 1.47 (m; 2H; H3); 1.58 (m; 2H; H18), 1.80 (m; 2H; H2); 3.99 (t; 2H; H1′; ³J_{1,2}=6.5 Hz); 6.97 (m; 2H; H2″); 7.30 (m; 1H; H8″); 7.41 (m; 2H; H7″); 7.51 (m; 2H; H3″); 7.55 (m; 2H; H6″)

¹³C-NMR: (126 MHz, CDCl3) 22.2 (C18); 24.3 (C17); 26.1; 29.0; 29.3; 29.3; 29.4; 29.6; 29.7 (C2 to C15); 31.8 (C16); 68.1 (C1); 114.7 (C2″); 126.6 (C8″); 126.7 (C6″); 128.1 (C3″); 128.7 (C7″); 133.5 (C4″); 140.9 (C5″); 158.7 (C1″)

### EXAMPLE 3

### Preparation of (17-thien-2′-ylheptadecyl)trichlorosilane (a) and (18-thien-2′-yloctadecyl)trichlorosilane (b)

The preparation of 2-heptadec-16′-enylthiophene and 2-octadec-17′-enylthiophene is effected in a first synthesis step by reaction of the respective bromoalkene or with 2-thienyllithium which was prepared beforehand from thiophene and n-BuLi. In order to avoid a complicated purification, 2-thienyllithium is used in a large excess in long reaction times and under mild conditions.

After column chromatography, the alkenylthiophenes are each obtained in 84% yield for 2-heptadec-16′-enylthiophene and in 90% yield for 2-octadec-17′-enylthiophene.

Starting from the two alkenylthiophenes 2-heptadec-16′-enylthiophene and 2-octadec-17′-enylthiophene, the corresponding trichlorosilane (17-thien-2′-ylheptadecyl)-trichlorosilane or (18-thien-2′-yloctadecyl)trichlorosilane was prepared in the second synthesis step in each case in a hydrosilylation with trichlorosilane and hexachloroplatinic acid as a catalyst.

After distillation (17-thien-2′-ylheptadecyl)trichlorosilane (a) was isolated in 84% yield and (18-thien-2′-yloctadecyl)trichlorosilane (b) in 83% yield, based on the respective olefin, as colorless liquid.

On the basis of mass spectrometry, ¹H— and ¹³C-NMR spectra, it was found that the compounds were the desired ones.

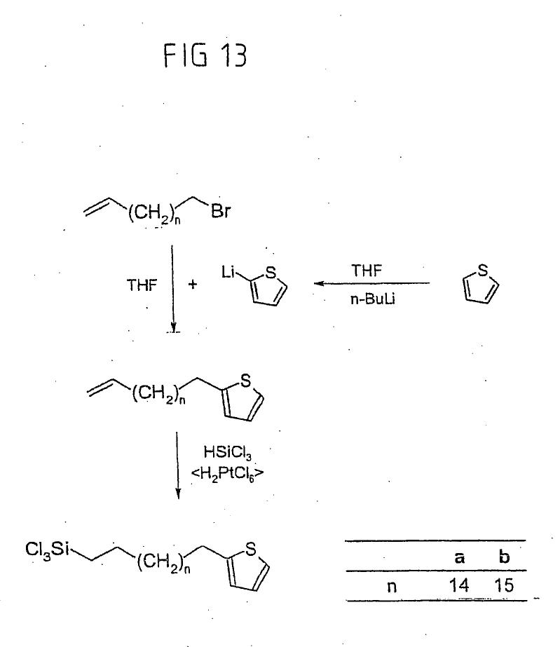

FIG. 13 shows the two synthesis steps together.

### 1st synthesis step: Preparation of 2-heptadec-16′-enylthiophene (for case a))

| | | | | |
|---|---|---|---|---|
| Batch: | Thiophene: | 10.6 | ml | 119 mmol |
| | n-BuLi: | 40 | ml | 65.6 mmol |
| | THF: | 100 | ml | |
| | 17-Bromoheptadecene: | 5 | g | 15.8 mmol |

40 ml of n-BuLi solution (15% strength in hexane) are initially introduced under an inert gas atmosphere into a heated two-necked flask having a rubber septum and cooled to −10° C. before 100 ml of THF are added. 10 g of thiophene are added by means of a syringe while cooling in the course of 10 min, a yellow coloration resulting. After the addition of all the thiophene, heating to room temperature is effected and 5 g of 17-bromoheptadecene are added in one portion. Stirring is then effected overnight at the same temperature.

For working-up, hydrolysis is effected with ice water and, after the organic phase has been separated off, the aqueous phase is extracted three times with dimethyl ether. The combined organic phases are dried over sodium sulfate. The removal of the solvent on a rotary evaporator gives a yellow oil, which is purified by chromatography over silica gel using n-hexane as the mobile phase.

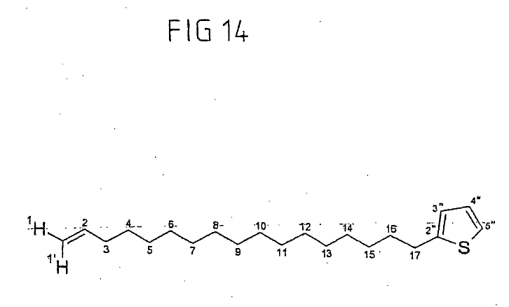

Yield: 4.25 g (13.3 mmol) of 84% 2-heptadec-16′-enylthiophene (cf. FIG. 14); colorless oil;

¹H-NMR: (250 MHz, CDCl3) 1.26 to 1.31 (m; 24H; H4 to H15); 1.67 (m; 2H; H16); 2.03 (m; 2H; H3); 2.79 (t; 2H; H17; ³J_{17,16}=7.6); 4.90 to 5.03 (m; 2H; H1+H1′); 5.81 (ddt; 1H; H2; ³J_{2,1′}=17.1; ³J_{2,1}=10.2; ³J_{2,3}=6.7); 6.77 (m; 1H; H3″); 6.90 (dd; 1H; H4″; ³J_{4,5}=5.1; ³J_{4″,3″}=3.4); 7.09 (dd; 1H; H5″; ³J_{5″,4″}=5.1; ⁴J_{5″,3″}=1.1)

¹³C-NMR: (63 MHz, CDCl3) 29.0; 29.2; 29.4; 29.6; 29.7; 29.9 (C2 to C16); 31.8 (C17); 33.9 (C3); 114.1 (C1); 122.7 (C5″); 123.9 (C3″); 126.6 (C4″); 139.3 (C2); 145.8 (C2″)

### 2nd synthesis step: Preparation of (17-thien-2′-ylheptadecyl)trichlorosilane (case a))

| | | | | |
|---|---|---|---|---|
| Batch: | 2-Heptadec-16′-enylthiophene: | 2.55 | g | 7.95 mmol |
| | Trichlorosilane: | 8.0 | ml | 79.5 mmol |
| | Hexachloroplatinic acid solution: | 10 | drops | |

2-Heptadec-16′-enylthiophene is initially introduced into a heated two-necked flask having a reflux condenser/gas discharge tube with valve/argon balloon and rubber septum. Trichlorosilane and the catalyst solution are added by means of a syringe and stirring is effected overnight at room temperature.

After removal of the excess trichlorosilane in a vacuum from a water jet pump, the residue is distilled over a Vigreux column under a vacuum from an oil pump.

Preparation of the catalyst solution:

164 mg of H₂PtCl₆ aq. are dissolved in 10 ml of absolute isopropanol. The solution is stirred until complete dissolution of the solid and is stored in a refrigerator.

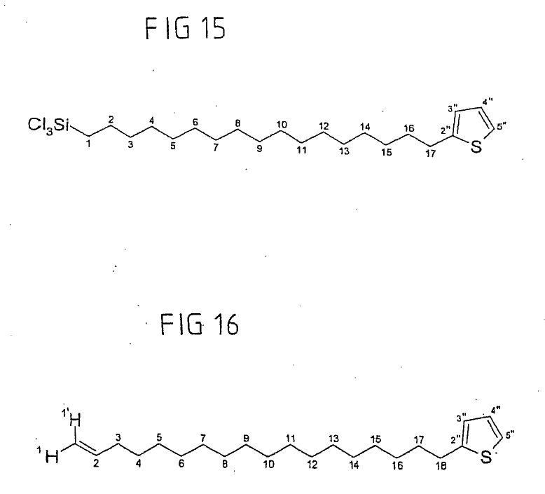

Yield: 3.03 g (6.64 mmol) of 84% (17-thien-2′-ylheptadecyl)trichlorosilane (cf. FIG. 15); colorless oil

Boiling point: 155-177° C. at 1×10⁻³ mmHg

MS: (EI 70 eV) C₂₁H₃₇Cl3Ssi Calc.: 454.1450 Found: 454.1450

¹H-NMR: (500 MHz, CDCl3) 1.26 to 1.43 (m; 28H; H2 to H15), 1.57 (m; 2H; H1), 1.67 (m; 2H; H16); 2.81 (t; 2H; H17; ³J_{17,16}=7.7); 6.77 (dd, 1H, H3″; ³J_{3″,4″}=3.1; ⁴J_{3″,5″}=1.0); 6.90 (dd; 1H; H4″; ³J_{4″,5″}=5.1; ³J_{5″3″}=3.3); 7.09 (dd; 1H; H5″,; ³J_{5″,4″}=5.1; ⁴J_{5″,3″}=1.0)

¹³C-NMR: (125 MHz, CDCl3) 22.3 (C1); 24.3 (C2); 29.0; 29.1; 29.4; 29.6; 29.6; 29.6; 29.7; 29.9 (C3 to C16); 31.8 (C17); 122.7 (C5″) 123.9 (C3″); 126.6 (C4″); 145.9 (C2″)

Infrared spectroscopy (CCl₄): ν(Si—Cl)=589; m: δₛ (CH₂)=1465: w; (CH₂=2854; s; νₐₛ(CH₂)=2928; vs

### 1st synthesis step: Preparation of 2-octadec-17′-enylthiophene (case b))

| | | | | |
|---|---|---|---|---|
| Batch: | Thiophene: | 24.8 | ml | 259 mmol |
| | n-BuLi: | 93.5 | ml | 65.6 mmol |
| | THF: | 240 | ml | |
| | 17-Bromooctadec-1-ene: | 12.1 | g | 36.6 mmol |

93.5 ml of n-BuLi solution (15% strength in hexane) are initially introduced under an inert gas atmosphere into a heated two-necked flask having a rubber septum and are cooled to −10° C. before 240 ml of THF are added. 24.8 ml of thiophene are added by means of a syringe in the course of 10 min while cooling, a yellow coloration resulting. After the addition of all the thiophene, the mixture is allowed to warm up to room temperature and 12.1 g of 18-bromooctadec-1-ene are added in one portion. Stirring is then effected overnight at the same temperature.

For working-up, hydrolysis is effected with ice water and, after the organic phase has been separated off, the aqueous phase is extracted three times with diethyl ether. The combined organic phases are dried over sodium sulfate. The removal of the solvent in a rotary evaporator gives a yellow oil, which is purified by chromatography over silica gel using n-hexane as the mobile phase.

Yield: 11.1 g (33.1 mmol) of 90% 2-octadec-17′-enylthiophene (cf. FIG. 16); colorless oil

Analysis: C₂₄H₄₀S (M: 334.60 g/mol) Calc.: C: 78.97 H: 11.45 S: 9.58 Found: C: 79.26 H: 11.58 S: 9.39

¹H-NMR: 500 MHz, CDCl₃) 1.21 to 1.43 (m; 26H; H4 to H16), 1.67 (m; 2H; H17), 2.04 (m; 2H; H3), 2.81 (t; 2H; H18; ³J_{18,17}=7.7), 4.92 (m_{c}; 1H; H1); 4.99 (m_{c}; 1H; H1′); 5.81 (ddt; 1H; H2, ³J_{2,1′}=17.1; ³J_{2,1}=10.2; ³J_{2,3}=6.7); 6.77 (dd; 1H; H3″; ³J_{3″,4″}=3.4; ⁴J_{3″,5″}=0.8); 6.90 (dd, 1H, H4; ³J_{4″,5″}=5.1, ³J_{4″,3″}=3.4); 7.09 (dd, 1H, H5″; ³J_{5″,4″}=5.1; ⁴J_{5″,3″}=0.8)

¹³C-NMR: (126 MHz, CDCl₃) 29.0; 29.1; 29.2; 29.4; 29.5; 29.6; 26.6; 29.7; 29.7; 29.9 (C2 to C17); 31.8 (C18); 33.8 (C3); 114.1 (C1); 122.7 (C5″); 123.9 (C3″); 126.6 (C4″); 139.3 (C2); 145.9 (C2″)

### 2nd synthesis step: Preparation of (18-thien-2-yloctadecyl)trichlorosilane (case b))

| | | | | |
|---|---|---|---|---|
| Batch: | 2-Octadec-17′-enylthiophene: | 7 | g | 20.9 mmol |
| | Trichlorosilane: | 21.1 | ml | 209 mmol |
| | Hexachloroplatinic acid solution: | 10 | drops | |

2-Octadec-17′-enylthiophene is initially introduced into a heated two-necked flask having a reflux condenser/gas discharge tube with valve/argon balloon and rubber septum. Trichlorosilane and the catalyst solution are added by means of a syringe and stirring is effected overnight at room temperature.

After removal of the excess trichlorosilane in a vacuum from a water jet pump, the residue is distilled over a Vigreux column under a vacuum from an oil pump.

Preparation of the catalyst solution: 164 mg of H₂PtCl₆ aq. are dissolved in 10 ml of absolute isopropanol. The solution is stirred until complete dissolution of the solid and is stored in a refrigerator.

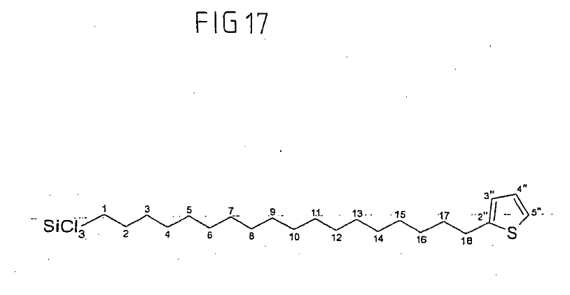

Yield: 8.13 g (17.3 mmol) of 83% (18-thien-2′-yloctadecyl)trichlorosilane (cf. FIG. 17); colorless oil

Boiling point: 183-211° C. at 5×10⁴ mmHg

MS: (EI 70 eV) C₂₂H₃₉Cl₃Ssi Calc.: 468.1607 Found: 468.1607

¹H-NMR: (500 MHz, CDCl₃) 1.26 to 1.44 (m; 30H; H2 to H16), 1.57 (m; 2H; H1), 1.67 (m; 2H; H17); 2.81 (t; 2H; H18; ³J_{17,16}=7.7); 6.77 (dd; 1H; H3″; ³J_{3″,4″}=3.3; ⁴J_{3″,5″}=0.9); 6.90 (dd, 1H; H4″; ³J_{4″,5″}=5.1; ³J_{4″,3″}=3.4); 7.09 (dd; 1H; H5″; ³J_{5″,4″}=5.1; ⁴J_{5″3″}=0.9)

¹³C-NMR: (125 MHz, CDCl₃) 22.7 (C1); 24.7 (C2); 29.4; 29.6; 29.8; 30.0; 30.0; 30.0; 30.0; 30.3 (C3 to C17); 32.2 (C18); 123.1 (C5″); 123.3 (C3″); 127.0 (C4″); 146.3 (C2″)

### EXAMPLE 4

### Synthesis of 4-(18′-trichlorosilyloctadecyloxy)benzonitrile

In order to influence as little as possible the properties of an amine forming on the monolayer 11,4-hydroxybenzonitrile is chosen as a starting material. This is reacted with 18-bromooctadec-1-ene in a Williamson ether synthesis in the first synthesis step. The 4-octadec-17′-enyloxybenzonitrile formed may be obtained in an 80% yield in reagent grade purity after chromatographic purification.

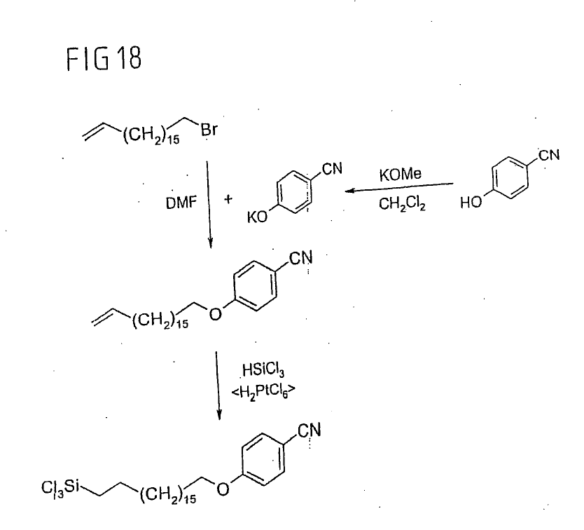

In the second synthesis step, 4-octadec-17′-enyloxybenzonitrile is hydrosilylated with trichlorosilane in a platinum-catalyzed reaction. After distillation, it was obtained as a colorless solid in good yield (82%). The characterization of 4-(18′-trichlorosilyloctadecyloxy)benzonitrile was effected by means of ¹H— and ¹³C-NMR and mass spectrometry. The two synthesis steps are shown together in FIG. 18, and the details of the synthesis steps will be discussed below.

### 1st synthesis step: Synthesis of 4-octadec-17′-enyloxybenzonitrile

| | | | | |
|---|---|---|---|---|
| Batch: | 4-Hydroxybenzonitrile: | 6.55 | g | 55 mmol |
| | KOMe: | 3.85 | g | 54.9 mmol |
| | CH₂Cl₂: | 75 | ml | |
| | 18-Bromooctadec-1-ene: | 13.3 | g | 40 mmol |
| | DMF: | 75 | ml | |

Preparation of potassium phenolate: 4-Hydroxybenzonitrile in CH₂Cl₂ is initially introduced into a flask, and KOMe is added. The reaction mixture is stirred for 15 min at room temperature, after which the solvent is completely removed in vacuo.

Ether coupling: DMF and the corresponding alkyl bromide are added to the potassium phenolate and heated to 120° C. After 2 h, the reaction is brought to room temperature, water is added and neutralization is effected with dilute HCl.

Working-up: The aqueous DMF phase is extracted several times with ether in a separating funnel. The organic phase is washed DMF-free with water and dried over MgSO₄. After removal of the solvent and purification over silica gel using PE/CH₂Cl₂ (1:1) as mobile phase, a colorless solid is obtained.

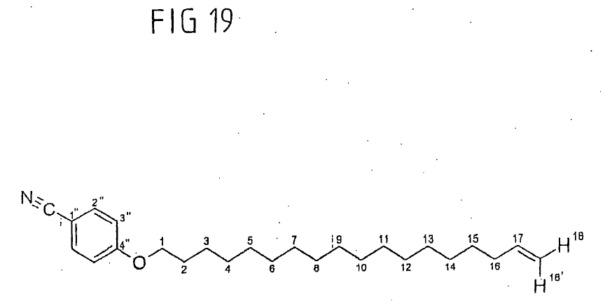

Yield: 11.8 g (31.8 mmol) of 80% 4-octadec-17′-enyloxybenzonitrile (cf. FIG. 19); colorless solid

Melting point: 60-61° C.

Analysis: C₂₅H₃₉NO (M: 369.59 g/mol) Calc.: C: 81.25 H: 10.64 N: 3.19 O: 4.33 Found: C: 81.13 H: 10.10 N: 3.56 O: —

¹H-NMR: (500 MHz, CDCl₃) 1.22 to 1.46 (m; 24H; H3-H15); 1.76 to 1.82 (m; 2H; H2); 2.01 to 2.06 (m; 2H; H16); 3.99 (t; 2H; H1; ³J_{1,2}=6.6 Hz); 4.92 (m_{c}; 1H; H18); 4.99 (m_{c}; 1H; H18′); 5.81 (ddt; 1H; H17; ³J_{17,18′}=17.0 Hz; ³J_{17,18}=10.2 Hz; J_{17,16}=6.9 Hz); 6.93 (m, 3H; H3″); 7.56 (m, 2H; H2″)

¹³C-NMR: (126 MHz, CDCl₃) 25.9; 29.0; 29.0; 29.2; 29.3; 29.5; 29.5; 29.6; 29.6; 29.7; 29.7 (C2-C15); 33.8 (C16); 68.4 (C1); 103.7 (C1″); 114.1 (C18); 115.2 (C3″); 119.3 (CN); 133.9 (C2″); 139.2 (C17); 162.5 (C4″) clp 2nd synthesis step: Preparation of 4-(18′-trichlorosilyloctadecyloxy)benzonitrile

| | | | | |
|---|---|---|---|---|
| Batch: | 4-Octadec-17′-enyloxybenzonitrile: | 5 | g | 13.5 mmol |
| | Trichlorosilane: | 24 | ml | 234 mmol |
| | Hexachloroplatinic acid solution: | 100 | μl | |

4-Octadec-17′-enyloxybenzonitrile is initially introduced into a heated two-necked flask having a reflux condenser/gas discharge tube with valve/argon balloon and rubber septum. Trichlorosilane and the catalyst solution are added by means of a syringe and stirring is effected overnight at room temperature. After removal of excess trichlorosilane in a vacuum from a water jet pump, the residue is distilled over a Vigreux column under a vacuum from an oil pump.

Preparation of the catalyst solution: 164 mg of H₂PtCl₆ aq. are dissolved in 10 ml of absolute isopropanol. The solution is stirred until complete dissolution of the solid and is stored in a refrigerator.

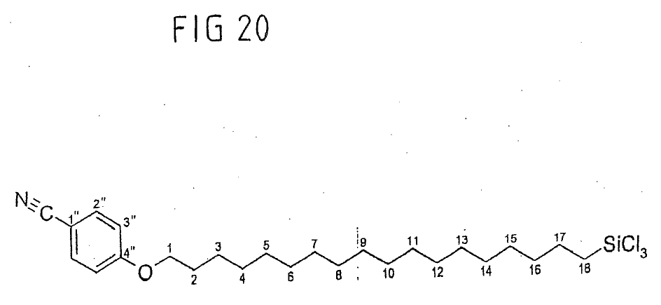

Yield: 5.61 g (11.1 mmol) of 82% 4-(18′-trichlorosilyloctadecyloxy)benzonitrile (cf. FIG. 20); colorless solid

Melting point: 50° C.

Boiling point: 211-237° C. at 5×10⁻⁵ mbar

MS: (EI 70 eV) C₂₅H₄₀Cl₃NOSi Calc.: 503.1945 Found: 503.1946

¹H-NMR: (500 MHz, CDCl₃) 1.22 to 1.48 (m; 30H; H3 to H17); 1.55 to 1.61 (m; 4H; H18); 1.77 to 1.82 (m; 2H; H2); 3.99 (t; 2H; H1; ³J_{1,2}=6.6 Hz); 6.93 (m; 3H; H3″); 7.55 (m; 2H; H2″)

¹³C-NMR: (126 MHz, CDCl₃) 22.2 (C18); 24.3 (C17); 25.9; 29.0; 29.3; 29.3; 29.5; 29.6; 29.6; 29.7 (C2-C15); 31.8 (C16); 68.4 (C1); 103.6 (C1″); 115.2 (C3″); 119.3 (CN); 134.0 (C2″); 162.5 (C4″)

With the aid of these ω-haloalk-1-enes (I), it is possible to form self-assembled monolayers 11. The use of the synthesized compounds is described below.

FIG. 21 shows a structural formula for an embodiment of a compound according to the invention. The compound has a substantially linear structure. Arranged at one end is an anchor group 1, which is in the form of trichlorosilane here. This anchor group 1 permits binding to a substrate 10, which is not shown here (cf. FIG. 22). Arranged above the anchor group 1 is a dielectric group 2, which is in the form of n-alkyl. The chain length is n=2 to 20. A head group 3 having an aromatic system is arranged at that end of the compound 5, which is opposite the anchor group 1. This head group 3 permits a π-π interaction with other molecules of the same type and/or molecules of another type for stabilization of the monolayer 11.

This is shown in FIG. 22, where molecules of the same type form a monolayer 11, which has a layer structure. The anchor groups 1 of the molecules are bound here to a hydroxyl-containing layer of a substrate 10. A π-π interaction can take place between the head groups 3 so that an extremely stable layer structure forms.

The advantages of these monolayers 11 (T-SAM) are explained in more detail below.

Chemical stability: The T-SAM is inert to all reagents which do not destroy the bond to the substrate surface. The T-SAMs are resistant for a certain time to aggressive reagents since the reagents first have to diffuse through the monolayer 11 or have to attack this from the side. This robustness was not observed to date for any other SAM class.

Process stability: The T-SAMs tolerate lithographic steps, such as the application of a photoresist, photostructuring, wet development and the stripping of photoresist. It is thus possible to build up further layers for the formation of an organic field effect transistor, for example on dielectric layers.

Stability as a function of time and storage stability: There may be several weeks between the deposition and further processing without there being any degradation of the T-SAM; the monolayers 11 are stable.

Metal deposition: Metals may be deposited electrochemically or via the gas phase onto the T-SAMs extensively in virtually 100% yield without short-circuits occurring. This high dielectric “quality” has not been observed to date in any other SAM class.

Thermal stability: The T-SAMs are stable to temperatures above 200° C.

Homogeneity of layer thickness: The layer thickness obtained is an intrinsic function of the molecular geometry and of the anchoring to the substrate. There are virtually no variations in layer thickness.

Finally, the structure of an organic field effect transistor which has layers on the synthesized compounds is to be explained.

Organic field effect transistors are electronic components which consist of a plurality of layers, all of which are structured in order to generate integrated circuits by connections of individual layers. FIG. 23 shows the fundamental structure of such a transistor in a bottom contact architecture.

A gate electrode 21 which is covered by a gate dielectric layer 22 is arranged on a base substrate 20. Such a gate dielectric layer 22 may consist, for example, of a monolayer 11 described above. Such dielectrics have a layer thickness of less than 5 nm (bottom up). Arranged on the gate dielectric layer 22 are a source layer 23a and a drain layer 23b, both of which are connected to an active semiconductor layer 24 on top. A passivation layer 25 is arranged above the active layer 24.

The invention is not limited in its execution to the above-mentioned preferred embodiments. Rather, a number of variants are conceivable, which make use of the synthesis method according to the invention, the compound according to the invention and the layer structure according to the invention also in versions of fundamentally different types.

What is claimed is:

1. A synthesis method for a compound used to form a self-assembled monolayer for a semiconductor component, the method comprising:
a first synthesis step comprising reacting an ω-haloalk-1-ene according to a reaction scheme represented by (I); 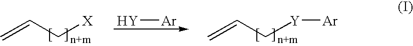
wherein the reaction scheme (I) comprises a terminal nucleophilic substitution of a halogen by a group capable of a π-π interaction, the group having at least one aromatic group (Ar); and
hydrosilylating a product of the first synthesis step in a second synthesis step.

2. The method of claim 1, wherein the group capable of the π-π interaction corresponds to the general formula HY—Ar, wherein Y is O, S, Se or NH.

3. The method of claim 1, wherein the aromatic group (Ar) comprises at least one of the following groups: 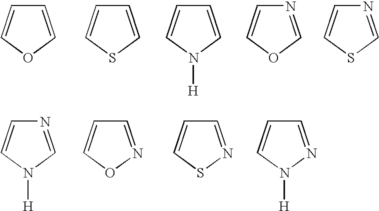
Furan Thiophene Pyrrole Oxazole Thiazole Imidazole Isoxazole Isothiazole Pyrazole 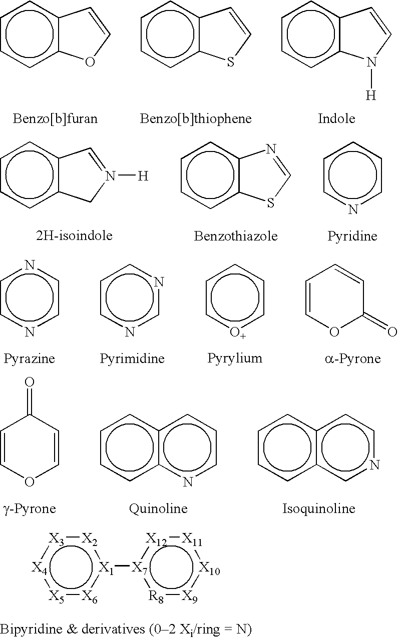
naphthalene, anthracene, naphthacene, pentacene, biphenyl, terphenyl, quaterphenyl, and quinquephenyl.

4. The method of claim 1, wherein the molecular group capable of the π-π interaction has a condensed aromatic having up to five ring systems.

5. The method of claim 1, wherein the hydrosilylation of the second synthesis step comprises an acid catalyzed reaction.

6. The method of claim 1, wherein the hydrosilylation of the second synthesis step comprises using a silane having the general formula HSiZ₃, wherein Z is Cl or an alkoxy group.

7. The method of claim 1, wherein the ω-haloalk-1-ene of the first synthesis step is prepared by a reaction according to the following reaction scheme:

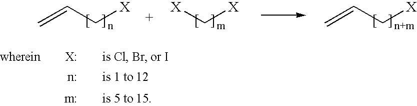

8. The method of claim 1, wherein the first synthesis step comprises forming octadec-17-enyloxybenzene by reacting an 18-bromooctadec-1-ene with potassium phenolate and DMF.

9. The method of claim 8, further comprising forming 4-octadec-17″-enyloxy-1,1′-biphenyl by reacting the 18-bromooctadec-1-ene with potassium biphenyl-4-olate and DMF.

10. The method of claim 8, further comprising forming at least one of 2-heptadec-16′-enylthiophene and 2-octadec-17′-enylthiophene by reacting the 18-bromooctadec-1-ene with 2-thienyllithium and THF.

11. The method of claim 8, further comprising using a Williamson ether synthesis to form 4-octadec-17′-enyloxybenzonitrile, wherein the Williamson ether synthesis comprises reacting a 4-hydroxybenzonitrile with the 18-bromooctadec-1-ene and DMF.

12. The method of claim 5, the acid catalyst is hexachloroplatinic(IV) acid.

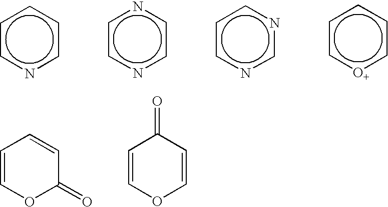

13. The method of claim 7, wherein n=6, and m=7.

14. A method of synthesizing an organic dielectric, the method comprising:
a first step comprising replacing a terminal halogen of an ω-haloalk-1-ene with a compound having at least one aromatic group, thereby yielding a reaction product comprising at least one of octadec-17-enyloxybenzene, 4-octadec-17″-enyloxy-1,1′-biphenyl, 2-heptadec-16′-enylthiophene, and 2-octadec-17′-enylthiophene;
a second step comprising hydrosilylating the reaction product of the first step.

15. The method of claim 14, wherein the compound having at least one aromatic group is selected from the group consisting essentially of furan, thiophene, pyrrole, oxazole, thiazole, imidazole, isoxazole, isothiazole, pyrazole, benzo[b]furan, benzo[b]thiophene, indole, 2H-isoindole, benzothiazole, pyridine, pyrazine, pyrimidine, pyrylium, α-pyrone, γ-pyrone, quinoline, isoquinoline, bipyridine, naphthalene, anthracene, naphthacene, pentacene, biphenyl, terphenyl, quaterphenyl, quinquephenyl, and derivatives thereof.

16. The method of claim 14, wherein the hydrosilylation of the second step comprises using a silane having the general formula HSiZ₃, wherein Z is Cl or an alkoxy group.

17. The method of claim 16, wherein the hydrosilylation comprises an acid catalyzed reaction.

18. The method of claim 17, the acid catalyst is hexachloroplatinic(IV) acid.

19. A semiconductor component having an organic compound arranged in molecular monolayer, wherein the organic compound is selected from the group consisting essentially of (18-phenoxyoctadecyl)trichlorosilane, [18-(1′,1″-biphenyl-4′-yloxy)octadecyl]trichlorosilane, (17-thien-2′-ylheptadecyl)trichlorosilane, (18-thien-2′-yloctadecyl)trichlorosilane, 4-(18′-trichlorosilyloctadecyloxy)benzonitrile, and combinations thereof.

20. The semiconductor component of claim 19, wherein the semiconductor component is an organic field effect transistor.
